(19) United States
(12) Patent Application Publication
(10) Pub. No.: US 2006/0289939 A1
(43) Pub. Date: Dec. 28, 2006

(54) Array substrate and display device having the same

(75) Inventors: Kyung-Hoon Kim, Euiwang-si (KR); Il-Gon Kim, Seoul (KR); Kook-Chul Moon, Yongin-si (KR); Tae-Hyeong Park, Yongin-si (KR); Chul-Ho Kim, Seoul (KR); Gyung-Soon Park, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/473,851

(22) Filed: Jun. 23, 2006

(30) Foreign Application Priority Data
Jun. 23, 2005 (KR) 2005-54646

(51) Int. Cl. H01L 29/94

(52) U.S. Cl. 257/368

(57) ABSTRACT

An LCD display device in which the gate lines are controlled by a gate circuit part that outputs gate signals to the gate lines. A first signal wiring is formed adjacent to the gate circuit part and transmits a starting signal, which initiates an operation of the gate circuit part, to the gate circuit part. A second signal wiring is formed at a side of the first signal wiring and transmits a control signal, which controls an output of the gate circuit part, to the gate circuit part. A first connection wiring is electrically connected between the gate circuit part and the second signal wiring. The first connection wiring is intersected with the first signal wiring. Therefore, a resistance of the wiring is increased to protect the gate circuit from static electricity.

### CROSS-REFERENCE TO RELATED APPLICATIONS

This application claims priority under 35 USC § 119 to Korean Patent Application No. 2005-54646, filed on Jun. 23, 2005, the contents of which are herein incorporated by reference in their entireties.

### BACKGROUND OF THE INVENTION

1. Field of the Invention

The present invention relates to an array substrate for a display device protected from static electricity.

2. Description of the Related Art

Generally, a liquid crystal display (LCD) device includes an LCD panel having an array substrate, an opposing substrate facing the array substrate, a liquid crystal layer interposed between the array substrate and the opposing substrate, and a driving unit for driving the LCD panel. The array substrate includes a plurality of gate lines, a plurality of data lines and a plurality of switching elements, such as thin-film transistors (TFTs) electrically connected to the gate lines and the data lines. During the LCD panel manufacturing process, static electricity may be generated and may cause wiring defects such as a short or an open circuit, and damage to the TFTs.

Recently, in order to decrease a size of the LCD device, the driving circuitry for the gate lines has been integrated into the LCD panel. The gate-driving circuit may be formed as a single shift register dependently connected to a plurality of stages. Therefore, since signal wiring as well as the gate-driving circuits are formed on the LCD panel, the LCD panel may be damaged due to static electricity. Particularly, the stages to which the vertical starting signal STV is applied may be frequently damaged due to the static electricity.

### SUMMARY OF THE INVENTION

The present invention provides an array substrate that is protected against static electricity during manufacture of the array substrate. According to one aspect of the present invention, first signal wiring is arranged adjacent to the gate circuit part to transmit a starting signal that initiates operation of the gate circuit part. Second signal wiring is arranged at a side of the first signal wiring to transmit a control signal which controls the output of the gate circuit part. First connection wiring is electrically connected between the gate circuit part and the second signal wiring, and is intersected with the first signal wiring. The gate circuit part includes a plurality of stages for applying gate signals to the gate lines. Clock signal wiring is arranged at a side of the starting signal wiring to transmit a clock signal which controls the output of the stages. Voltage wiring is arranged at a side of the clock signal wiring to transmit a driving voltage to the gate circuit part. The first connection wiring is electrically connected between the gate circuit part and the clock signal wiring, and is intersected with the starting signal wiring. The second connection wiring is electrically connected between the gate circuit part and the voltage signal wiring, and is intersected with the starting signal wiring.

One of the substrates of the display includes a display region and a peripheral region which has the gate circuitry, the signal wiring for transmitting a driving signal to the gate signal part, and connection wiring connecting the gate circuit part to the signal wirings. The signal wirings include a first signal wiring for transmitting a starting signal. The first signal wiring is adjacent to the gate circuit part, and is intersected with the connection wiring made of material different from that of the starting signal wiring; thus, the resistance of the wirings is increased so that the gate circuit part electrically connected to the starting signal wirings is protected from static electricity.

### BRIEF DESCRIPTION OF THE DRAWINGS

The above and other features and advantages of the present invention will become more apparent by describing in detailed example embodiments thereof with reference to the accompanying drawings, in which:

FIG. 1 is a plan view illustrating an array substrate in accordance with an example embodiment of the present invention;

FIG. 2 is an enlarged plan view illustrating the array substrate in FIG. 1;

FIG. 3 is a cross-sectional view of the array substrate taken along a line I-I′ in FIG. 2;

FIG. 4 is a block diagram illustrating a gate circuit part in FIG. 1;

FIG. 5 is an internal circuit diagram illustrating the stages in FIG. 4;

FIG. 6 is a plan view illustrating a liquid crystal display (LCD) device in an example embodiment of the present invention; and

FIG. 7 is a cross-sectional view of the LCD device taken along a line II-II′ in FIG. 6.

### DESCRIPTION OF THE EMBODIMENTS

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items. Spatially relative terms, such as “beneath,” “below,” “lower,” “above,” “upper” and the like, may be used herein for ease of description to describe one element or feature's relationship to another element(s) or feature(s) as illustrated in the figures.

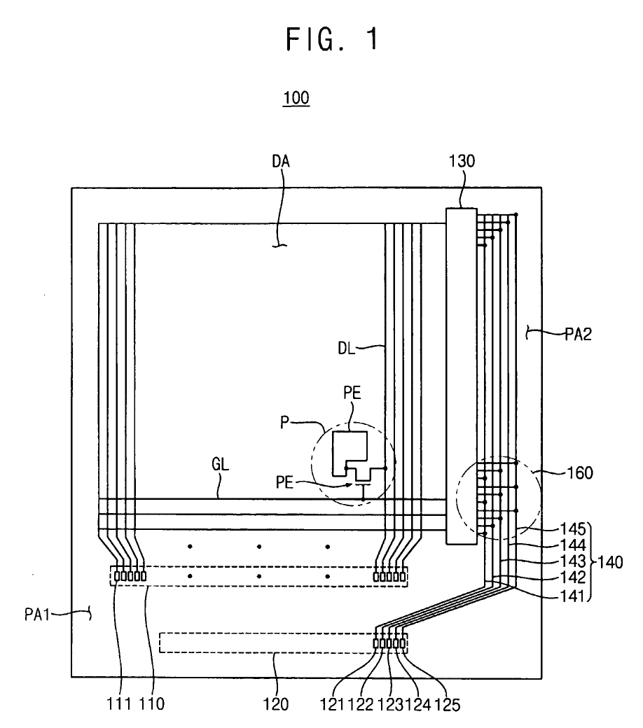

FIG. 1 is a plan view illustrating an array substrate in accordance with an example embodiment of the present invention. Referring to FIG. 1, an array substrate 100 includes a display region DA and a peripheral region PA surrounding the display region DA. A plurality of gate lines GL, a plurality of data lines DL and a plurality of pixels P defined by the gate lines GL and the date lines DL are formed in the display region DA. A switching element (i.e., a thin-film transistor or TFT) electrically connected to the gate lines GL and the date lines DL, and a pixel electrode PE electrically connected to the switching element are formed in each of the pixels P. Although not shown in FIG. 1, a storage common line as a common electrode of a storage capacitor may be formed in the pixels P. The peripheral region PA includes a first peripheral region PA1 and a second peripheral region PA2.

The first peripheral region PA1 includes a first pad portion 110 and a second pad portion 120. The first pad portion 110 includes a plurality of pads 111, each pad 111 extending from an end of one of the data lines DL. A driving chip, which outputs a driving signal to the pixels P, is mounted on the first pad portion 110. The driving signal includes data signals transmitted to the pixels P. An output terminal of a flexible printed circuit board FPCB, which transmits an external signal provided from an external device to the driving chip mounted on the first pad portion 110, makes contact with the second pad portion 120.

A gate circuit part 130, a signal wiring part 140 and a connection wiring part 160 are formed in the second peripheral region PA2. The gate circuit part 130 outputs a gate signal to the gate lines GL. The signal wiring part 140 transmits a gate control signal to the gate circuit part 130. The connection wiring part 160 is electrically connected between the gate circuit part 130 and the signal wiring part 140. The gate circuit part 130 may be a shift register that is dependently connected to a plurality of stages corresponding to the gate lines GL. Signal wiring part 140 may include first, second, third, fourth and fifth signal wires 141, 142, 143, 144 and 145 substantially parallel to the data lines DL. The signal wiring part 140 may include a metal substantially the same as that of the data lines DL.

The first signal wiring 141 transmits a first gate voltage VDD for determining the high level of the gate signal to the gate circuit part 130. The second signal wiring 142 transmits a vertical starting signal STV as a control signal for starting the operation of the gate circuit part 130. The second signal wiring 142 is electrically connected to a first stage and a last stage of the gate circuit part 130.

The third signal wiring 143 transmits a first clock signal CK for controlling the output of the odd-numbered gate signals. The fourth signal wiring 144 transmits a second clock signal CKB for controlling the output of the even-numbered gate signals. The fifth signal wiring 145 transmits a second gate voltage VSS for determining the low level of the gate signal to the gate circuit part 130.

The first signal wiring 141 is arranged adjacent to the gate circuit part 130. The second signal wiring 142 is disposed adjacent to the first signal wiring 141. The third signal wiring 143 is positioned adjacent to the second signal wiring 142. The fourth signal wiring 144 is arranged adjacent to the third signal wiring 143. The fifth signal wiring 145 is positioned adjacent to the fourth signal wiring 144.

First, second, third, fourth and fifth pads 121, 122, 123, 124 and 125 are formed at ends of the first to the fifth signal wirings 141, 142, 143, 144 and 145, respectively. The second pad portion 120 formed in the first peripheral region PA1 includes the first to the fifth pads 121, 122, 123, 124 and 125.

The connection wiring part 160 may be formed using a material substantially the same as that of the gate lines GL. The connection wiring part 160 is positioned on a plane different from that on which the data lines DL is placed. The connection wiring part 160 is substantially parallel to the gate lines GL. That is, the connection wiring part 160 extends in a direction intersecting the signal wiring part 140. The connection wiring part 160 includes a plurality of connection wirings electrically connected between the first, second, third, fourth and fifth signal wirings 141 to 145 and the gate circuit part 130. For example, a first connection wiring is electrically connected between input terminals of the first stage and the first to the fifth signal wirings.

The connection wiring part 160 is arranged in a direction intersecting the second signal wiring 142 for transmitting the vertical starting signal STV. That is, the second signal wiring 142 has a structure that is partially overlapped with the connection wiring part 160 including the material substantially the same as that of the gate lines GL.

As a result, since a portion of the second signal wiring 142 overlapped with the connection wiring part 160 has an increased capacitance, static electricity flowing into the second signal wiring 142 may be dispersed. Therefore, electronic elements, which may be electrically connected to the second signal wiring 142, may be protected from the static electricity.

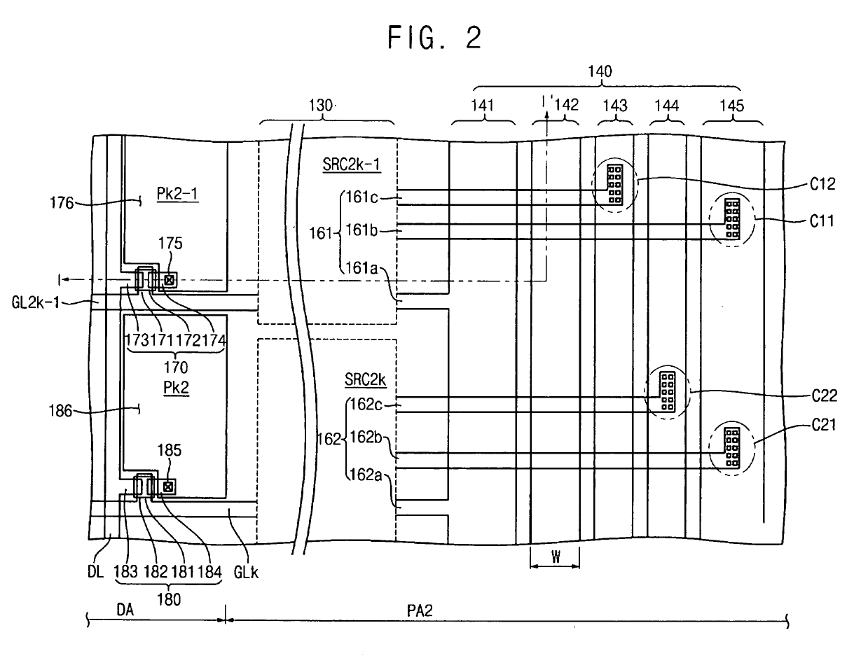

FIG. 2 is an enlarged plan view illustrating the array substrate in FIG. 1. Referring to FIGS. 1 and 2, the array substrate 100 includes the first and second peripheral regions PA1 and PA2 and the display region DA. A plurality of stages SRC2k−1 and SRC2k of the gate circuit part 130, the signal wiring part 140 and a plurality of the connection wiring parts 161 and 162 electrically connected between the plurality of the stages SRC2k−1 and SRC to the signal wiring part 140 are formed in the second peripheral region PA2. The plurality of the stages SRC2k−1 and SRC2k includes a plurality of TFTs. Each of the TFTs includes a gate electrode formed from a gate metal pattern, a source/drain electrode formed from a data metal pattern, and a channel layer formed using amorphous silicon.

The signal wiring part (i.e., the first, second, third, fourth and fifth signal wirings 141, 142, 143, 144 and 145) corresponding to a part of the data metal pattern extends in a direction substantially parallel to the data lines DL formed in the display region DA. The second signal wiring 142 is positioned adjacent to the gate circuit part 130. The second signal wiring 142 transmits the vertical starting signal STV from the second pad 122 to the gate circuit part 130. The third to fifth signal wirings 143 to 145 are sequentially arranged at a side of the second signal wiring 142. The third to fifth signal wirings 143 to 145 transmit the first and the second clock signals CK and CKB. The second signal wiring 142 may be formed between the gate circuit part 130 and the third signal wiring 143. The second signal wiring 142 has a width of about 60 μm.

The connection wiring parts 161 and 162 corresponding to a part of the gate metal pattern extend in a direction substantially parallel to the gate lines GL formed in the display region DA. Each of the connection wiring parts 161 and 162 electrically interconnects the signal wiring part 140 and each of the plurality of the stages SRC2k−1 and SRC2k. Particularly, the first gate voltage VDD transmitted to the first signal wiring 141, the second gate voltage VSS transmitted applied to the fifth signal wiring 145, and the first clock signal CK transmitted to the third signal wiring 143 are applied to the odd-numbered stage SRC2k−1. Therefore, the first connection wiring part 161 electrically connecting the odd-numbered stage SRC2k−1 to the signal wiring part 140 includes first, second and third connection wirings 161a, 161b and 161c.

The first connection wiring 161a extends from the first signal wiring 141 and is electrically connected to input terminals of the odd-numbered stage SRC2k−1. The second connection wiring 161b is electrically connected to the fifth signal wiring 145 through a contact part C11 and is then coupled to the input terminals of the odd-numbered stage SRC2k−1. The third connection wiring 161c is electrically connected to the third signal wiring 143 through a contact part C12 and is then coupled to the input terminals of the odd-numbered stages SRC2k−1. Here, in this example embodiment, the first connection wiring 161a formed as a part of the data metal pattern extends from the first signal wiring 141. Alternatively, the first connection wiring 161a may be formed as a part of the gate metal pattern.

Meanwhile, the first gate voltage VDD transmitted to the first signal wiring 141, the second gate voltage VSS transmitted to the fifth signal wiring 145, and the second clock signal CKB transmitted to the fourth signal wiring 144 are applied to the even-numbered stages SRC2k. Therefore, the second connection wiring part 162 electrically connecting the odd-numbered stage SRC2k to the signal wiring part 140 includes first, second and third connection wirings 162a, 162b and 162c. The first connection wiring 162a extends from the first signal wiring 141 to be electrically connected to input terminals of the even-numbered stages SRC2k. The second connection wiring 162b is electrically connected to the fifth signal wiring 145 through a contact part C21 to be coupled to the input terminals of the even-numbered stages SRC2k. The third connection wiring 162c is electrically connected to the fourth signal wiring 144 through a contact part C22 to be coupled to the input terminals of the even-numbered stages SRC2k.

Here, in this example embodiment, the first connection wiring 162a formed as a part of the date metal pattern extends from the first signal wiring 141. Alternatively, the first connection wiring 161a may be formed as a part of the gate metal pattern. Thus, the second signal wiring 142 for transmitting the vertical starting signal STV is partially overlapped with the second and the third connection wirings 161b and 161c among the connection wirings of the odd-numbered stages SRC2k−1. Further, the second signal wiring 142 is partially overlapped with the second and the third connection wirings 162b and 162c among the connection wirings of the even-numbered stages SRC2k.

As a result, a resistance of the second signal wiring 142 increases due to the second and the third connection wirings that are electrically connected to the plurality of the stages, respectively. When the resistance of the second signal wiring 142 is augmented, static electricity flowing to the second signal wiring is dispersed to protect the first and the last stages, which are electrically connected to the second signal wiring, from the static electricity.

The display region DA includes a plurality of pixels P2k−1 and P2k. A first switching element 170 that is electrically connected to a (2k−1)-th gate line GL2k−1, which is coupled to the output terminals of the odd-numbered stage SRC2k−1, is formed on the (2k−1)-th pixel P2k−1. Particularly, the first switching element 170 includes a first gate electrode 171, a first source electrode 173 and a first drain electrode 174. The first gate electrode 171 is coupled to the (2k−1)-th gate line GL2k−1. The first source electrode 173 is electrically connected to the data lines DL. The first drain electrode 174 is electrically connected to a first pixel electrode 176 through a first contact pad 175. The first switching element 170 further includes a first channel portion 172 formed between the first gate electrode 171 and the first source/drain electrodes 173 and 174.

A second switching element 180, which is electrically connected to a 2k-th gate line GL2k coupled to the output terminals of the even-numbered stage SRC2k, is formed on the 2k-th pixel P2k. Particularly, the second switching element 180 includes a second gate electrode 181, a second source electrode 182 and a second drain electrode 184. The second gate electrode 181 is coupled to the 2k-th gate line GL2k. The second source electrode 182 is electrically connected to the data line DL. The second drain electrode 184 is electrically connected to a first pixel electrode 186 through a second contact pad 185. The second switching element 180 further includes a second channel portion 182 formed between the second gate electrode 181 and the second source/drain electrodes 183 and 184.

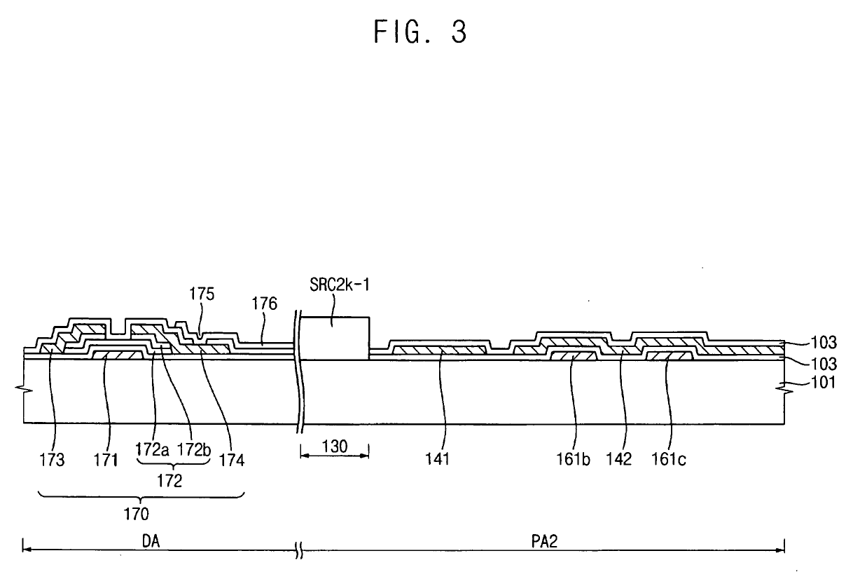

FIG. 3 is a cross-sectional view of the array substrate taken along a line I-I′ in FIG. 2. Referring to FIGS. 1 to 3, the array substrate 100 includes a base substrate 101 having the display region DA and the peripheral regions PA1 and PA2. After a gate metal layer is formed on the base substrate 101, the gate metal layer is partially etched to form a gate metal pattern on the base substrate 101.

The gate metal pattern includes the gate lines GL2k−1 and GL2k, the gate circuit part 130 and the second and third connection wirings 161b, 161c, 162b and 162c of the connection wiring part 160. The contact parts C11, C12, C21 and C22 including a plurality of the contact holes are formed at ends of the first and the second connection wirings 161b, 161c, 162b and 162c. The contact parts C11, C12, C21 and C22 electrically connect the third to fifth signal wirings 143, 144, 145 to the first and second connection wirings 161b, 161c, 162b and 162c.

A gate insulation layer 102 is formed on the base substrate 101 including the gate metal pattern. After a channel layer is formed on the gate insulation layer 102, the channel layer is patterned to form a first channel portion 172 and a second channel portion 182 on the gate insulation layer. Here, the channel layer includes active layers 172a and 182a formed using amorphous silicon, and ohmic contact layers 172b and 182b formed using polysilicon doped in situ with N-type impurities.

After a data metal layer is formed on the base substrate 101 including the first and the second channel portions 172 and 182, the data metal layer is patterned to form a data metal pattern on the base substrate 101. The date metal pattern includes the data lines DL, the first and second source electrodes 173 and 183, the first and second drain electrodes 174 and 184, the gate circuit part 130 and the first, second, third, fourth and fifth signal wirings 141 to 145. Further, the date metal pattern includes the first connection wirings 161a and 162a extending from the first signal wiring 141 to be coupled to the input terminals of stages SRC2k−1 and SRC2k, respectively.

When the second and the third connection wirings 161b, 161c, 162b and 162c are arranged under the second signal wiring 142 to which the vertical starting signal is transmitted, a resistance of the second signal wiring 142 may increase. Thus, the stage coupled to the second signal wiring 142 may be protected from static electricity.

The ohmic contact layer 172b of the first channel portion 172 is partially removed from the base substrate 101 using the first source/drain electrodes 173 and 174 as an etching mask to define a channel region of the first switching element 170. Further, the ohmic contact layer 182b of the second channel portion 182 is partially removed from the base substrate 101 using the first source/drain electrodes 183 and 184 as an etching mask to define a channel region of the second switching element 180.

A passivation layer 103 is formed on the base substrate 101 including the data metal pattern. The passivation layer 103 is partially removed from the base substrate 101 to form the first and the second contact holes 175 and 185 through which the upper faces of the first and the second drain electrodes 174 and 184 are exposed. Although not shown, a plurality of contact holes for electrically connecting a plurality of switching elements to each other may be further formed through the gate circuit part 130.

A pixel electrode layer is formed on the base substrate 101 including the first and the second contact holes 175 and 185. The pixel electrode layer is patterned to form a first pixel electrode 176 and a second pixel electrode 186. An example of the pixel electrode layer may include a transparent conductive material such as indium-tin-oxide (ITO), indium-zinc-oxide (IZO) or indium-tin-zinc-oxide (ITZO).

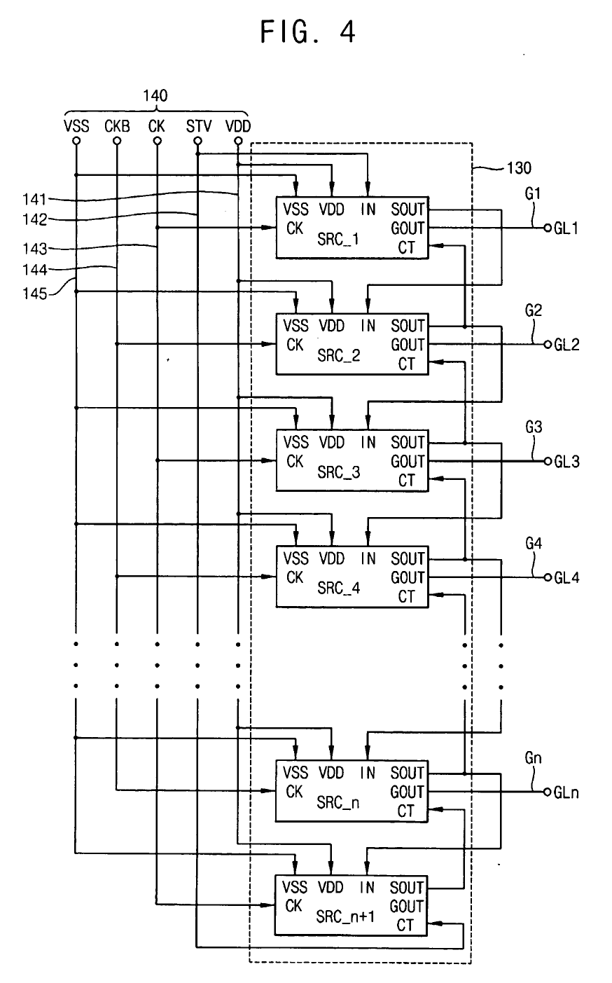

FIG. 4 is a block diagram illustrating the gate circuit part in FIG. 1. Referring to FIG. 4, the gate circuit part 130 may correspond to a shift register including a plurality of stages SRC_1 to SRC_n+1, which are dependently connected to one another. The signal wiring part 140 is formed at a lateral portion of the gate circuit part 130. The signal wiring part 140 transmits a driving signal for operating the gate circuit part 130 to the gate circuit part 130.

The signal wiring part 140 includes the first, second, third, fourth and fifth signal wirings 141 to 145. The first signal wiring 141 transmits the first gate voltage VDD in accordance with the driving signal generated by the gate circuit part 130. The second signal wiring 142 transmits the vertical starting signal STV. The third signal wiring 143 transmits the first clock signal CK. The fourth signal wiring 144 transmits the second clock signal CKB. The fifth signal wiring 145 transmits the second gate voltage VSS.

The plurality of the stages SRC_1 to SRC_n+1 includes the first to Nth driving stages SRC_1 to SRC_n and one dummy stage SRC_n+1. Each of the stages SRC_1 to SRC_n+1 includes an input terminal IN, a clock terminal CK, a control terminal CT, a first output terminal GOUT and a second output terminal SOUT. The clock terminal CK receives the first clock signal CK or the second clock signal CKB.

For example, the first clock signal CK is applied to the odd-numbered stages SRC_1, SRC_3, . . . , SRC_n+1 of the plurality of the stages SRC_1 to SRC_n+1, whereas the second clock signal CKB is applied to the even-numbered stages SRC_2, SRC_4, . . . , SRC_n thereof. Each of the first output terminals GOUT of the odd-numbered stages SRC_1, SRC_3, . . . , SRC_n+1 responds to the first clock signal CK to output odd-numbered gate signals G1, G3, . . . , Gn−1. Each of the first output terminals GOUT of the even-numbered stages SRC_2, SRC_4, . . . , SRC_n−1 responds to the second clock signal CKB to output even-numbered gate signals G2, G4, . . . Gn.

Particularly, the first output terminals GOUT of the first to Nth stages SRC_1 to SRC_n is one-to-one connected to the odd-numbered gate lines GL1, GL3, . . . , GL2n−1. Thus, gate signals transmitted by the first output terminals GOUT of the first to Nth stages SRC_1 to SRC_n are sequentially applied to the odd-numbered gate lines GL1, GL3, . . . , GL2n−1. Here, since there is no gate line corresponding to the first output terminal GOUT of the dummy stage SRC_On+1, the first output terminal GOUT of the dummy stage SRC_On+1 is in a floating state. Each of the second output terminals SOUT of the odd-numbered stages SRC_1, SRC_3, . . . , SRC_n+1 outputs the first clock signal CK as a stage control signal. Each of the second output terminals SOUT of the even-numbered stages SRC_2, SRC_4, . . . , SRC_n outputs the second clock signal CKB as a stage control signal.

Particularly, an input terminal IN of the first stage SRC_1 receives a control signal outputted from the second output terminal SOUT of the previous stage, and the control terminal CT receives a control signal outputted from the second output terminal SOUT of the next stage. However, since a previous stage does not exist before the first stage SRC_1, the input terminal of the first stage SRC_1 receives the vertical starting signal STV. Further, since a next stage does not exist after the dummy stage SRC_n+1, the control terminal CT of the dummy stage SRC_n+1 receives the vertical starting signal STV. Thus, the first stage SRC_1 and the last stage SRC_n+1 receive the vertical starting signal STV.

Each of the stages SRC_1 to SRC_n+1 further includes the first voltage terminal VDD and the second voltage terminal VSS. The first voltage terminal VDD receives the first gate voltage VDD for determining a high level of the gate signals. The second voltage terminal VSS receives the second gate voltage VSS for determining a low level of the gate signals.

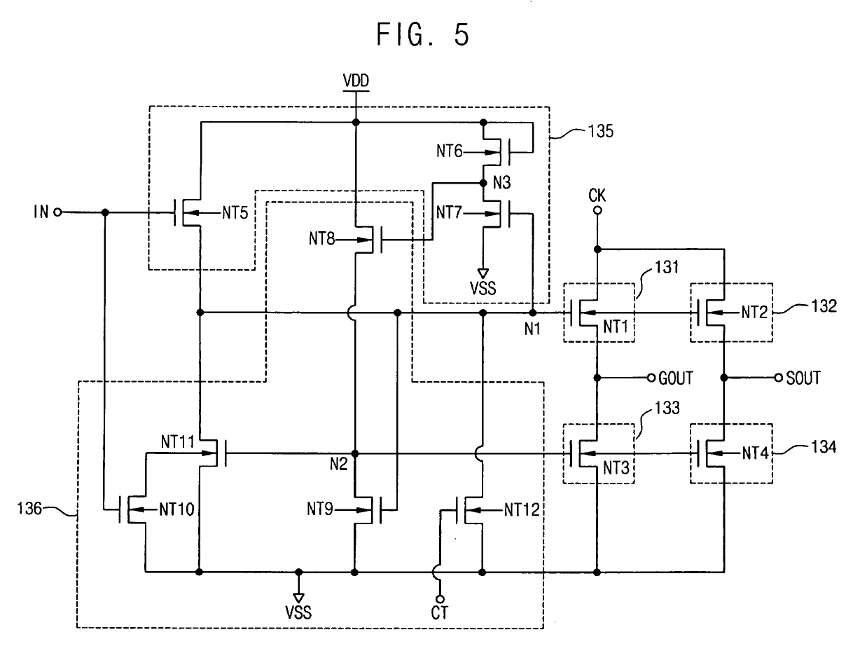

FIG. 5 is an internal circuit diagram illustrating the stages in FIG. 4. Referring to FIG. 5, each of the stages includes a first pull-up part 131, a second pull-up part 132, a first pull-down part 133, a second pull-down part 134, a pull-up operation part 135 and a pull-down operation part 136. The first pull-up part 131 responds to the clock signals CK or CKB applied to the clock terminal CK to output the gate signal to the first output terminal GOUT. The second pull-up part 132 responds to the clock signals CK or CKB applied to the clock terminal CK to output the control signal to the first output terminal SOUT.

The first pull-up part 131 includes a first transistor NT1. The first transistor NT1 includes the gate electrode connected to a first node N1, the source electrode connected to the clock terminal CK, and the drain electrode connected to the first output terminal GOUT. The second pull-up part 132 includes a second transistor NT2. The second transistor NT2 includes the gate electrode connected to a first node N1, the source electrode connected to the clock terminal CK, and the drain electrode connected to the second output terminal SOUT.

After the first pull-up part 131 turns off, the first pull-down part 133 turns on to discharge the gate signal transmitted from the first output terminal GOUT. On the other hand, after the second pull-up part 132 turns off, the second pull-down part 134 turns on to discharge the control signal transmitted from the second output terminal SOUT. The first pull-down part 133 includes a third transistor NT3. The third transistor NT3 includes a gate electrode connected to a second node N2, a source electrode connected to the second voltage terminal VSS, and a drain electrode connected to the first output terminal GOUT. The second pull-down part 134 includes a fourth transistor NT4. The fourth transistor NT4 includes a gate electrode connected to a first node N2, a source electrode connected to the second voltage terminal VSS, and a drain electrode connected to the second output terminal SOUT.

The pull-up driving part 135 includes fifth, sixth and seventh transistors NT5, NT6 and NT7 that turn on the first and second pull-up parts 131 and 132. The fifth transistor NT5 includes a gate electrode connected to the input terminal IN, a source electrode connected to the first node N1, and a drain electrode connected to the first voltage terminal VDD. The sixth transistor NT6 includes a gate electrode connected to the first voltage terminal VDD, a source electrode connected to the third node N3, and a drain electrode connected to the first voltage terminal VDD. The seventh transistor NT7 includes a gate electrode connected to the first node N1, a source electrode connected to the second voltage terminal VSS, and a drain electrode connected to the third node N3.

The pull-down driving part 136 includes eighth to twelfth transistors NT8, NT9, NT10, NT11 and NT12. The pull-down driving part 136 turns off the first and second pull-up parts 131 and 132, and turns on the first and second pull-down parts 133 and 134. The eighth transistor NT8 includes a gate electrode connected to the third node N3, a source electrode connected to the second node N2, and a drain electrode connected to the first voltage terminal VDD.

The ninth transistor NT9 includes a gate electrode connected to the first node N1, a source electrode connected to the voltage terminal VSS, and a drain electrode connected to the second node N2. The tenth transistor NT10 includes a gate electrode connected to the input terminal IN, a source electrode connected to the second voltage terminal VSS, and a drain electrode connected to the second node N2. The eleventh transistor NT11 includes a gate electrode connected to the second node N2, a source electrode connected to the second voltage terminal VSS, and a drain electrode connected to the first node N1. The twelfth transistor NT12 includes a gate electrode connected to the control terminal CT, a source electrode connected to the second voltage terminal VSS, and a drain electrode connected to the first node N1.

When the control signal transmitted through the second output terminal SOUT of the previous stage is applied to the input terminal IN, the fifth transistor NT5 is turned on to increase a voltage of the first node N1. As the voltage of the first node N1 is increased, the first and second transistors NT1 and NT2 are turned on such that the gate signal and the control signal are outputted from the first and the second output terminals GOUT and SOUT.

When the sixth transistor NT6 keeps turned on, a voltage of the first node N1 is increased such that the seventh transistor is turned on, thereby decreasing a voltage of the third node N3. As the voltage of the third node N3 is reduced, the eighth transistor NT8 keeps turned off. Thus, the driving voltage VDD is not applied to the second node N2. Further, when the voltage of the first node N1 is increased, the ninth transistor N9 is turned on to keep the voltage of the second node N2 to the second gate voltage VSS. Therefore, the third and fourth transistors N3 and N4 are turned off.

When the control signal is transmitted from the second output terminal SOUT of the next stage through the control terminal CT, the twelfth transistor N12 is turned on to discharge the voltage of the first node N1 to the second gate voltage VSS. As a voltage of the first node decreases, the seventh and ninth transistors NT7 and NT9 are turned on. Therefore, the voltage of the second node N2 is increased such that the third and fourth transistors NT3 and NT4 are turned on. The gate signal and the control signal, which are outputted from the first and the second output terminals GOUT and SOUT, are discharged to the second gate voltage VSS.

Here, the tenth and eleventh transistors NT10 and NT11 are turned on as the voltage of the second node N2 is increased, such that the voltage of the first node N1 is rapidly discharged. When the above-described process is repeated, each of the stages outputs the gate signal and the control signal for maintaining the high status for a predetermined time.

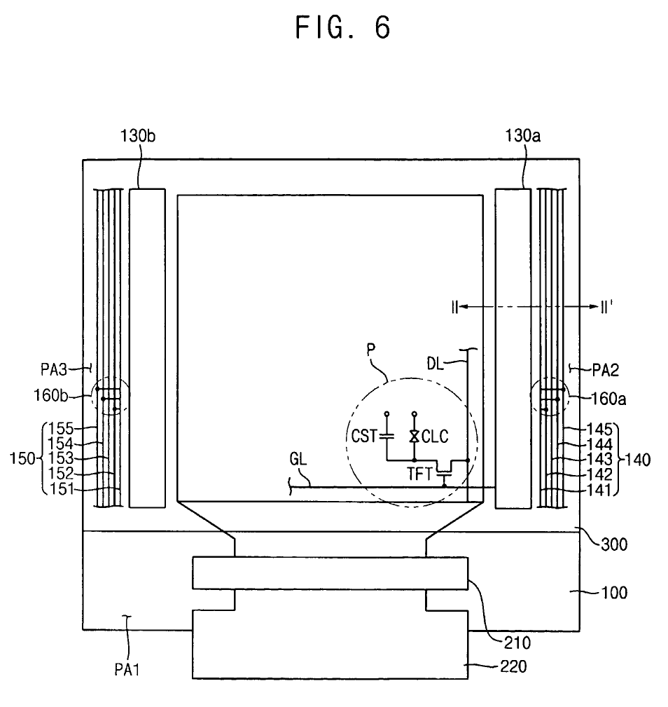

FIG. 6 is a plan view illustrating a liquid crystal display (LCD) device in an example embodiment of the present invention. Referring to FIGS. 1 to 6, the LCD device includes an LCD panel and a driving device. The LCD panel includes an array substrate 100, an opposing substrate 300 facing the array substrate 100 and a liquid crystal layer (not shown) sealed between the array substrate 100 and the opposing substrate 300 by a sealant 250. The driving device includes a driving chip 210 mounted on a first peripheral region PA1 of the array substrate 100, and a flexible printed circuit board 220 electrically connecting the driving chip 210 to an external device.

A first gate circuit part 130a, a first signal wiring part 140 and a first connection wiring part 160a are formed in a second peripheral region PA2. The first gate circuit part 130a generates a gate signal for odd-numbered gate lines. The first signal wiring part 140 transmits a first driving signal to the first gate circuit part 130a. A first connection wiring part 160a connects the first gate circuit part 130a to the first signal wiring part 140.

A second gate circuit part 130b, a second signal wiring part 150 and a second connection wiring part 160b are formed in a third peripheral region PA3. The second gate circuit part 130b generates a gate signal for the even-numbered gate lines. The second signal wiring part 150 transmits a second driving signal to the second gate circuit part 130b. The second connection wiring part 160b connects the second gate circuit part 130b to the second signal wiring part 150. The first signal wiring part 140 includes a first, second, third, fourth and fifth wiring 141 to 145. The first wiring 141 transmits a first gate voltage VDD. The second wiring 142 transmits a vertical starting signal STV. The third signal wiring 143 transmits a first clock signal CK. The fourth signal wiring 144 transmits a second clock signal CKB. The fifth signal wiring 145 transmits a second gate voltage VSS. The second signal wiring 142 is arranged adjacent to the first gate circuit part 130a. The third to the fifth signal wirings 143 to 145 are sequentially arranged near the second signal wiring 142.

The first connection wiring part 160a is intersected with the second signal wiring 142 to increase a resistance of the second signal wiring 142. When the resistance of the second signal wiring 142 is augmented, the first gate circuit part 130a, which is electrically connected to the second signal wiring 142, may be protected from static electricity.

The second signal wiring part 150 includes a first, second, third, fourth and fifth wiring 151 to 155. The first wiring 151 transmits a first gate voltage VDD. The second wiring 152 transmits a vertical starting signal STV. The third signal wiring 153 transmits a first clock signal CK. The fourth signal wiring 154 transmits a second clock signal CKB. The fifth signal wiring 155 transmits a second gate voltage VSS. The second signal wiring 152 is positioned adjacent to the second gate circuit part 130b. The third to the fifth signal wirings 153 to 155 are formed in sequence near the second signal wiring 152.

The second connection wiring part 160b connecting the second signal wiring part 150 to the second gate circuit part 130a is intersected with the second signal wiring 152 to increase a resistance of the second signal wiring 152. When the resistance of the second signal wiring 152 is augmented, the second gate circuit part 130b, which is electrically connected to the second signal wiring 152, may be protected from static electricity. The first and the second gate circuit parts 130a and 130b include a plurality of stages subordinately interconnected to each other. The driving circuit and driving flow of the first and the second gate circuit parts 130a and 130b are the same as those described with reference to FIGS. 4 and 5.

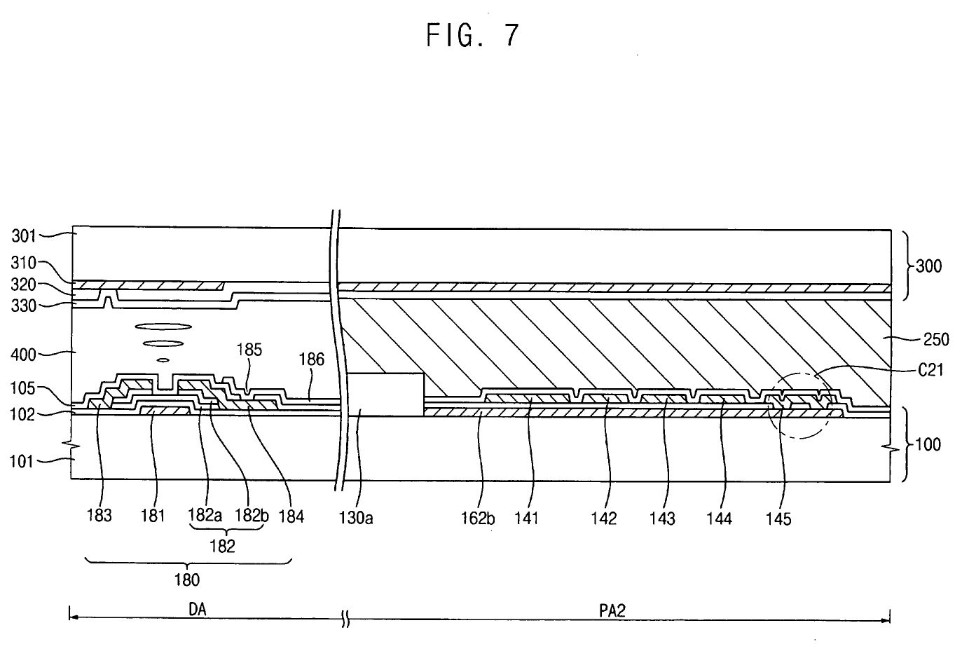

FIG. 7 is a cross-sectional view of the LCD device taken along a line II-II′ in FIG. 6. Referring to FIGS. 2 and 7, the LCD panel includes the array substrate 100, the opposing substrate 300 facing the array substrate 100 and the liquid crystal layer 400 interposed between the array substrate 100 and the opposing substrate 300. The array substrate 100 includes a first base substrate 101 having the display region DA and the peripheral regions PA1 and PA2. A plurality of the pixels P2k−1 and P2k is formed in the display region DA. A first switching element 170 and a first pixel electrode 176 are formed in the first pixel P2k. The first switching element 170 is electrically connected to a (2k−1)-th gate line GL2k−1 coupled to an output terminal of the odd-numbered stage SRC2k−1. The first pixel electrode 176 is electrically connected to the first switching element 170. The first switching element 170 includes a first gate electrode 171, a first channel portion 172, a first source electrode 173 and a first drain electrode 174.

A second switching element 180 and a second pixel electrode 186 are formed in the second pixel P2k−1. The second switching element 180 is electrically connected to a 2k-th gate line GL2k coupled to an output terminal of the even-numbered stage SRC2k. The second pixel electrode 186 is electrically connected to the second switching element 180. The second switching element 180 includes a second gate electrode 181, a second channel portion 182, a second source electrode 183 and a first drain electrode 184.

The gate circuit part 130, the signal wiring part 140 and a plurality of the connection wiring parts 161 and 162 are formed in the second peripheral region PA2. The signal wiring part 140 includes first, second, third, fourth and fifth signal wirings 141, 142, 143, 144 and 145. The connection wiring parts 161 and 162 electrically connect the signal wiring part 140 and each stage of the gate circuit part 130.

In this example embodiment of the present invention, the second signal wiring 142 is overlapped with the second and the third connection wirings 161b and 161c among the connection wirings connected to the odd-numbered stages SRC2k−1, and the second and the third connection wirings 162b and 162c among the connection wirings connected to the even-numbered stages SRC2k.

Thus, the second signal wiring 142 has an increased resistance due to the second and the third connection wirings, which are connected to a plurality of the stages, respectively. As the resistance of the second signal wiring 142 is increased, static electricity flowing into the second signal wiring may be dispersed such that the first and last stages coupled to the second signal wiring may be protected from the static electricity.

The opposing substrate 300 includes a second base substrate 301. The second base substrate includes a light masking layer 310, a color filter layer 320 and a common electrode layer 330. The light masking (or shielding) layer 310 defines a plurality of regions that correspond to the pixels formed on the array substrate 100, and blocks light leaked through the liquid crystal layer 400. The color filter layer 320 includes a red color pattern R, a green color pattern G and a blue color pattern B. The color filter layer 320 is formed in the plurality of regions defined by the light masking layer 310.

The common electrode layer 330 faces pixel electrodes 176 and 186 formed on the array substrate 100. The common electrode layer 330 corresponds to a second electrode of a liquid capacitor. The liquid crystal layer 400 is interposed between the array substrate 100 and the opposing substrate 300. An orientation angle of molecules in the liquid crystal layer 400 is changed in accordance with a potential difference between the pixel electrodes 176 and 186 and the common electrode layer 330.

Table 1 shows measured capacitances of the second signal wirings for transmitting the vertical starting signal STV in accordance with an example embodiment of the present invention.

TABLE 1

| | Test 1 | | | Test 2 | | |
|---|---|---|---|---|---|---|
| Model | 2.34-inch | | | 2.32-inch | | |
| | VGL_STV | STV | CK | REV 01 | REV 00 | |
| | SHORT | | | STV | STV | CK |
| | | | | CROSSOVER | | |
| Capacitance | 130 pF | 8 pF | 30 pF | 34 pF | 7 pF | 22 pF |

Test 1 indicates capacitances of signal wirings in a conventional 2.34-inch LCD panel. The signal wiring in the conventional 2.34-inch LCD panel is formed at the same position as the fifth signal wiring 145 formed outermost among the signal wirings of the signal wiring part 140 in FIG. 1.

In the conventional 2.34-inch LCD panel, defects may occur at a portion at which the gate circuit part is coupled to the vertical starting signal STV wiring. However, defects may not occur at a portion at which the gate circuit part is coupled to the clock signal wiring CK. Therefore, when the capacitances of the signal wirings in the convention 2.34-inch LCD panel were measured under a condition in which a wiring VGL for transmitting the second gate voltage VSS was shorted to a wiring for transmitting the vertical starting signal STV, a capacitance of the wiring VGL was about 130 pF, a capacitance of the vertical starting signal STV wiring was about 8 pF, and a capacitance of the clock signal CK wiring was about 30 pF. That is, it can be noted that the vertical starting signal STV wiring had a capacitance significantly lower than that of the clock signal CK wiring.

As a result, when the capacitance of the vertical starting signal STV wiring is higher than that of the clock signal CK wiring, defects may not occur.

Test 2 shows capacitances of signal wirings in a conventional 2.32-inch LCD panel REV 00 and capacitances of the vertical starting signal STV wiring of a 2.32-inch LCD panel REV 01 in accordance with an example embodiment of the present invention.

A capacitance of the vertical starting signal STV wiring in the conventional 2.32-inch LCD panel reached 7 pF. A capacitance of the clock signal wiring was 22 pF. Therefore, the vertical starting signal STV wiring had a capacitance much lower than that of the clock signal CK wiring. However, a capacitance of the vertical starting signal STV wiring in the 2.32-inch LCD panel in accordance with an example embodiment of the present invention reached 34 pF higher than the capacitance of the clock signal wiring, which amounted to 22 pF.

The vertical starting signal STV wiring is overlapped with the clock signal (CK or CKB) wiring and the second gate voltage VSS wiring such that a capacitance of the vertical starting signal STV wiring may increase. Thus, when the capacitance of the vertical starting signal STV wiring is higher than the capacitance of the clock signal wiring, it can be noted that the vertical starting signal STV wiring may be protected from static electricity, in a similar way as that of the clock signal wiring.

According to the present invention, a vertical starting signal wiring is intersected with connection wirings of other driving signal wirings transmitting a first gate voltage, a second gate voltage, a first clock signal, and a second clock signal. The vertical starting signal wiring may have an increased capacitance.

The vertical starting signal wiring is intersected with connection wirings connecting the gate circuit part to the first gate voltage VDD wiring and the first and the second clock signal wirings to increase a resistance of the vertical starting signal wiring. The capacitance of vertical starting signal wiring may increase to reach the capacitance formed by the connection wirings intersected with the first gate voltage VDD wiring. Therefore, the vertical starting signal wiring and an electronic element of the gate circuit part connected to the vertical starting signal wiring may be protected from static electricity.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. An array substrate comprising:
a plurality of pixels defined by gate lines and data lines;
a gate circuit part outputting gate signals to the gate lines;
a first signal wiring formed adjacent to the gate circuit part to transmit a starting signal, which initiates the gate circuit part, to the gate circuit part;
a second signal wiring formed at a side of the first signal wiring to transmit a control signal, which controls an output of the gate circuit part, to the gate circuit part; and
a first connection wiring electrically connected between the gate circuit part and the second signal wiring and intersected with the first signal wiring.

2. The array substrate of claim 1, further comprising:
a third signal wiring formed at the side of the first signal wiring to transmit an operating voltage to the gate circuit part; and
a second connection wiring electrically connected between the gate circuit part and the third signal wiring and intersected with the first signal wiring.

3. The array substrate of claim 2, wherein the second signal wiring is formed between the first signal wiring and the third signal wiring.

4. The array substrate of claim 1, wherein the gate circuit part includes a plurality of stages dependently coupled to each other.

5. The array substrate of claim 4, wherein the second signal wiring transmits a first clock signal to odd-numbered stages among the stages.

6. The array substrate of claim 5, wherein the first connection wiring is electrically connected to each of the odd-numbered stages to transmit a first clock signal to the odd-numbered stages.

7. The array substrate of claim 4, wherein the second signal wiring transmits the second clock signal to even-numbered stages among the stages

8. The array substrate of claim 7, wherein the first connection wiring is electrically connected to the even-numbered stages to transmit a second clock signal to the even-numbered stages.

9. The array substrate of claim 4, wherein the third signal wiring transmits a gate-off voltage that determines a low level of the gate signal.

10. The array substrate of claim 9, wherein the second connection wiring is electrically connected to the stages to transmit the gate-off voltage to the stages.

11. The array substrate of claim 1, wherein the first to third signal wirings include a metal substantially the same as that of the data lines.

12. The array substrate of claim 1, wherein the first and second connection wirings include a metal substantially the same as that of the gate lines.

13. The array substrate of claim 1, wherein each of the pixels includes a switching element connected to the gate lines and the data lines, and the switching element and the gate circuit part include amorphous silicon thin-film transistors (TFTs).

14. An array substrate comprising:
a plurality of pixels defined by gate lines and data lines;
a gate circuit part including a plurality of stages that output gate signals to the gate lines;
a starting signal wiring formed adjacent to the gate circuit part to transmit a starting signal, which initiates operation of the gate circuit part, to the gate circuit part;
a clock signal wiring formed at a side of the starting signal wiring to transmit a clock signal, which controls outputs of the stages, to the stages;
a voltage wiring formed at a side of the clock signal wiring to transmit a driving voltage to the gate circuit part;
a first connection wiring electrically connected between the gate circuit part and the clock signal wiring and intersected with the starting signal wiring; and
a second connection wiring electrically connected between the gate circuit part and the voltage signal wiring and intersected with the starting signal wiring.

15. A display device comprising:
a first substrate; and
a second substrate combined with the first substrate to receive a liquid crystal layer, the second substrate including a display region and a peripheral region, the display region having a plurality of pixels, and the peripheral region having a gate circuit part that outputs a gate signal, signal wirings that transmit a driving signal to the gate signal part, and connection wirings that are connected between the gate circuit part and the signal wirings,
wherein the signal wirings includes a first signal wiring that transmits a starting signal to the gate circuit part, the first signal wiring being adjacent to the gate circuit part and being intersected with the connection wirings.

16. The display device of claim 15, wherein the signal wirings further comprise:
a second signal wiring formed at a side of the first signal wiring to transmit a control signal, which controls an output of the gate circuit part, to the gate circuit part; and
a third signal wiring formed at a side of the second signal wiring to transmit the driving signal to the gate circuit part.

17. The display device of claim 15, wherein the connection wirings comprise:
a first connection wiring electrically connected between the gate circuit part and the second signal wiring; and
a second connection wiring electrically connected between the gate circuit part and the third signal wiring.

18. The display device of claim 17, wherein the gate circuit part includes a plurality of stages dependently connected to each other, the second signal wiring transmits a first clock signal to odd-numbered stages among the stages, and the first connection wiring is electrically connected to each of the odd-numbered stages.

19. The display device of claim 18, wherein the second signal wiring transmits a second clock signal to even-numbered stages among the stages, and the first connection wiring is electrically connected to each of the even-numbered stages.

20. The display device of claim 18, wherein the third signal wiring transmits a gate-off voltage, which determines a low level of the gate signal, to the stages, and the second connection wiring is electrically connected to each of the stages.

21. The display device of claim 17, wherein the gate circuit part comprises:
a first gate circuit part outputting the gate signal to odd-numbered gate lines among the gate lines; and
a second gate circuit part outputting the gate signal to even-numbered gate lines among the gate lines.
